(19) United States
(12) Patent Application Publication
(10) Pub. No.: US 2019/0245056 A1
(43) Pub. Date: Aug. 8, 2019

(54) FERROELECTRIC DEVICES FREE OF EXTENDED GRAIN BOUNDARIES

(71) Applicants: International Business Machines Corporation, Armonk, NY (US); Centre National De La Recherche Scientifique, Paris (FR); Ecole Centrale De Lyon, Écully (FR)

(72) Inventors: John Bruley, Poughkeepsie, NY (US); Eduard Albert Cartier, New York, NY (US); Catherine Dubourdieu, Berlin (DE); Martin Michael Frank, Dobbs Ferry, NY (US); Lucie Mazet, Grenoble (FR); Vijay Narayanan, New York, NY (US)

(21) Appl. No.: 15/886,876

(22) Filed: Feb. 2, 2018

(51) Int. Cl. H01L 29/51; H01L 27/088; H01L 29/66; H01L 49/02

(52) U.S. Cl. CPC H01L 29/516; H01L 28/55; H01L 29/6684; H01L 27/088

(57) ABSTRACT

A circuit and method relating to a ferroelectric region free of extended grain boundaries through a thickness of ferroelectric film. The circuit includes an interlayer insulating film disposed on a semiconductor wafer; a first conductive film disposed on the interlayer insulating film; a ferroelectric film disposed on the first conductive film; a second conductive film disposed on the ferroelectric film; and a ferroelectric region patterned from the ferroelectric film, wherein the ferroelectric region is free of extended grain boundaries through a thickness of the ferroelectric film. The method includes depositing an interlayer insulating film over a semiconductor wafer; depositing a first conductive film over the interlayer insulating film; depositing a ferroelectric film over the first conductive film; depositing a second conductive film over the ferroelectric film; and forming a capacitor by patterning the first conductive film, the second conductive film, and the ferroelectric film.

### FIELD OF THE INVENTION

The present invention relates to ferroelectric devices. More particularly, the present invention relates to ferroelectric devices free of extended grain boundaries.

### BACKGROUND

Ferroelectric materials are commonly used in devices such as random access memory (RAM) and capacitors. It is commonly understood that in order to exhibit a useable degree of ferroelectricity, ferroelectric materials have to be crystalline. While single-crystal ferroelectrics can be fabricated, in practical applications polycrystalline ferroelectric films are typically used. Often, the electrode size in ferroelectric devices is in the sub-micrometer scale. When electrode size is comparable to the typical size of the ferroelectric crystallites in the polycrystalline film, a countable number of grains is located underneath the top electrode. Statistical effects can then give rise to device-to-device variations in electrical properties which are affected by the number and shape of grains underneath the electrode.

### SUMMARY

The present invention provides for a circuit, the circuit includes an interlayer insulating film disposed on a semiconductor wafer; a first conductive film disposed on the interlayer insulating film; a ferroelectric film disposed on the first conductive film; a second conductive film disposed on the ferroelectric film; and a ferroelectric region patterned from the ferroelectric film, wherein the ferroelectric region is free of extended grain boundaries through a thickness of the ferroelectric film.

The present invention provides for an alternative circuit, the circuit includes a first field-effect transistor including a ferroelectric region patterned from a ferroelectric film; a second field-effect transistor including a ferroelectric region patterned from a ferroelectric film; the first field-effect transistor and the second field-effect transistor include conductive films; wherein the ferroelectric regions are free of extended grain boundaries throughout their thickness.

The present invention also provides for a method of manufacturing a circuit, the method includes depositing an interlayer insulating film over a semiconductor wafer; depositing a first conductive film over the interlayer insulating film; depositing a ferroelectric film over the first conductive film; depositing a second conductive film over the ferroelectric film; and forming a capacitor including a lower electrode and an upper electrode by patterning the first conductive film, the second conductive film, and the ferroelectric film.

### BRIEF DESCRIPTION OF THE DRAWINGS

Embodiments will be described in more detail in conjunction with the accompanying drawings, in which:

FIG. 1 illustrates a diagram of a circuit where the ferroelectric region is free of extended grain boundaries through a thickness of ferroelectric film;

FIG. 2 illustrates a diagram of a circuit including a lower capacitor electrode and an upper capacitor electrode which is patterned from the first conductive film, second conductive film, the ferroelectric film;

FIG. 3 illustrates a diagram of a circuit including the first field-effect transistor and the second field-effect transistor, wherein the circuit includes a ferroelectric region disposed on the channel regions of the first field-effect transistor and the second field-effect transistor, and wherein the ferroelectric regions are free of extended grain boundaries throughout their thickness;

FIG. 4 illustrates a flow chart for the circuit of FIG. 1;

FIG. 5 illustrates a flow chart for the circuit including a capacitor of FIG. 2;

FIG. 6 illustrates a flow chart for the circuit including field-effect transistors of FIG. 3; and

FIG. 7 illustrates example graphs that describe C-V measurements of an example capacitor structure.

### DETAILED DESCRIPTION

The present invention provides a circuit and method relating to where the ferroelectric region is free of extended grain boundaries through a thickness of ferroelectric film. The present invention is described in greater detail by referring to the following discussion and drawings that accompany the present disclosure.

It will be readily understood that components of the present invention, as generally described in the figures herein, can be arranged and designed in a wide variety of different configurations in addition to the presently described embodiments. Thus, the following detailed description of some embodiments of the present invention, as represented in the figures, is not intended to limit the scope of the present invention as claimed, but is merely representative of selected embodiments of the present invention.

For the sake of brevity, conventional techniques related to semiconductor device and IC fabrication may not be described in detail herein. Moreover, the various tasks and process steps described herein may be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In the following description, numerous specific details are set forth, such as particular structures, components, materials, dimensions, processing steps and techniques, in order to provide an understanding of the various embodiments of the present invention. However, it will be appreciated by one of ordinary skill in the art that the various embodiments of the present invention may be practiced without these specific details. In other instances, well-known structures or processing steps have not been described in detail in order to avoid obscuring the present invention.

The present invention is to be understood within the context of the description provided below. The description provided below is to be understood within the context of the Figures provided and described above. The Figures are intended for illustrative purposes and, as such, are not necessarily drawn to scale.

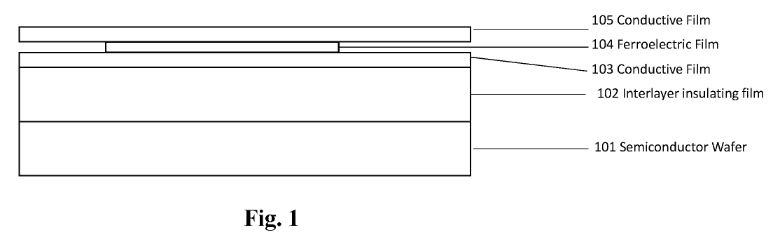

Referring to FIG. 1, a diagram of a circuit is illustrated. The circuit includes an interlayer insulating film 102 disposed on a semiconductor wafer 101. Then, a first conductive film 103 is disposed on the interlayer insulating film 102. Next, a ferroelectric film 104 is disposed on the first conductive film 103 and a second conductive film 105 is disposed on the ferroelectric film 104. A ferroelectric region is patterned from the ferroelectric film 104, wherein the ferroelectric region is free of extended grain boundaries through a thickness of ferroelectric film 104. The ferroelectric region can be a perovskite material. The perovskite material can include at least one of the following: Barium Titanate (BaTiO3), Lead Zirconium Titanate (PZT), or Strontium Bismuth Tantalate (SBT). The ferroelectric region can also include a characteristic crystallite size that is smaller than any dimension of a ferroelectric region in the circuit. The characteristic crystallite size allows for reduced statistical circuit variability.

The ferroelectric region can be amorphous, nanocrystalline, or glass-ceramic. This circuit can include a capacitor including a lower electrode and an upper electrode. This capacitor can be formed by patterning at least one of the first conductive film, the ferroelectric film, and the second conductive film. Additional films can be disposed between the interlayer insulating film 102 and the semiconductor wafer 101; the first conductive film 103 and interlayer insulating film 102; the ferroelectric film 104 and the first conductive film 103; the second conductive film 105 and the ferroelectric film 104, and any combination thereof.

Glass-ceramics are generally formed by the rapid quenching of a glass melt followed by a controlled re-heating which results in the crystallization of one or more phases in the glass matrix. Glass-ceramics containing a ferroelectric crystalline phase are properly referred to as ferroelectric glass-ceramics. The identification of the crystalline phase which is known to be ferroelectric in the single-crystal state is the principle used to categorize materials as ferroelectric glass-ceramics. Ferroelectric glass-ceramics generally exhibit broad peaks in a dielectric constant at nearly the same temperature as the single crystal, and the smaller the crystallite size, the greater the broadening.

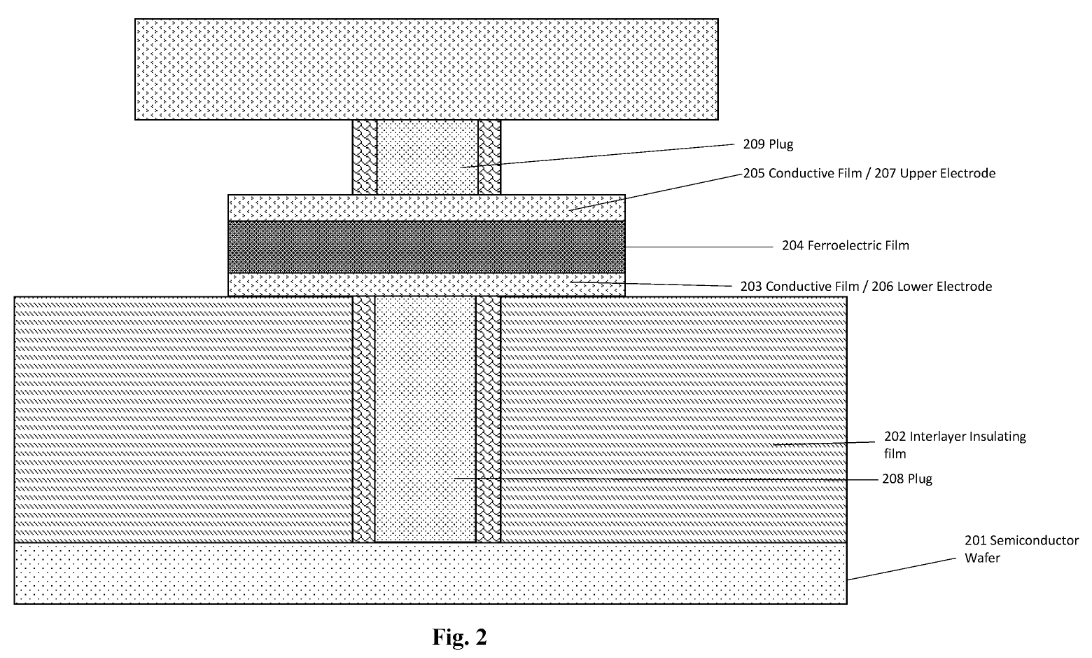

Referring to FIG. 2, which illustrates a diagram of a circuit including a capacitor. The circuit includes an interlayer insulating film 202 disposed on a semiconductor wafer 201, a first conductive film 203 disposed on the interlayer insulating film 202, a ferroelectric film 204 disposed on the first conductive film 203, and a second conductive film 205 disposed on the ferroelectric film 204. Finally, a capacitor is formed including a lower electrode 206 and an upper electrode 207 by patterning the first conductive film 203, second conductive film 205, the ferroelectric film 204. The lower electrode 206 can be formed from an oxygen barrier metal such as TiN, Pt, or Ir. The circuit structure can further include plug 208 and plug 209 to contact the capacitor. A plug can be deposited over the upper electrode 207 and a plug can be deposited between the interlayer insulating film 202. The capacitor fabrication process can be performed between transistor fabrication processes in the front-end of the line (FEOL) and metallization processes in the back-end of the line (BEOL), e.g. because the temperatures used in ferroelectric deposition and crystallization are often higher than those of the metallization process.

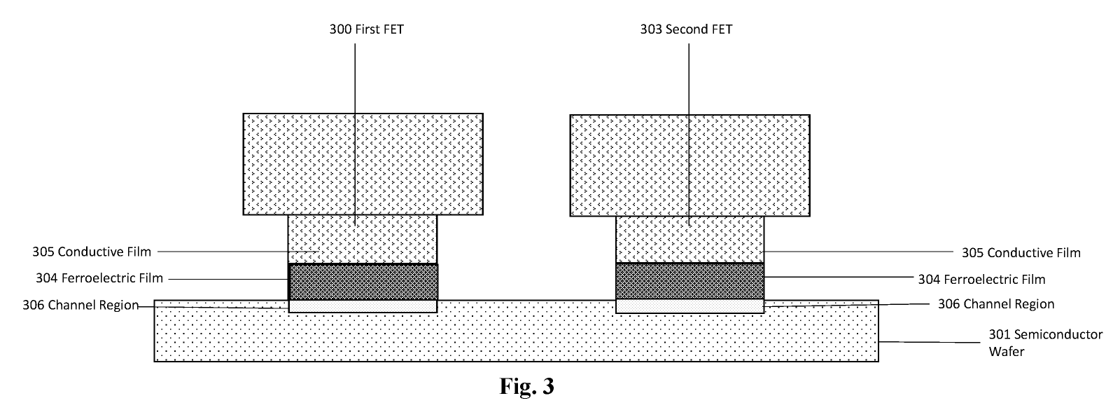

Referring to FIG. 3, which illustrates a diagram of a circuit disposed on a semiconductor wafer 301. The circuit includes a first field-effect transistor 300 and a second field-effect transistor 302. The first field-effect transistor 300 contains a ferroelectric region patterned from a ferroelectric film 304 disposed on a channel region 306, and a conductive film 305 disposed on the ferroelectric film 304. The second field-effect transistor 303 contains a ferroelectric region patterned from a ferroelectric film 304 disposed on a channel region 306, and a conductive film 305 disposed on the ferroelectric film 304. The ferroelectric regions are free of extended grain boundaries throughout their thickness. The ferroelectric region can include a characteristic crystallite size that is smaller than any dimension of a ferroelectric region in the circuit. The characteristic crystallite size allows for reduced statistical circuit variability. The ferroelectric region can be amorphous, nanocrystalline or glass-ceramic. Information can be stored in the gate ferroelectric layer and read out as a transistor drain current.

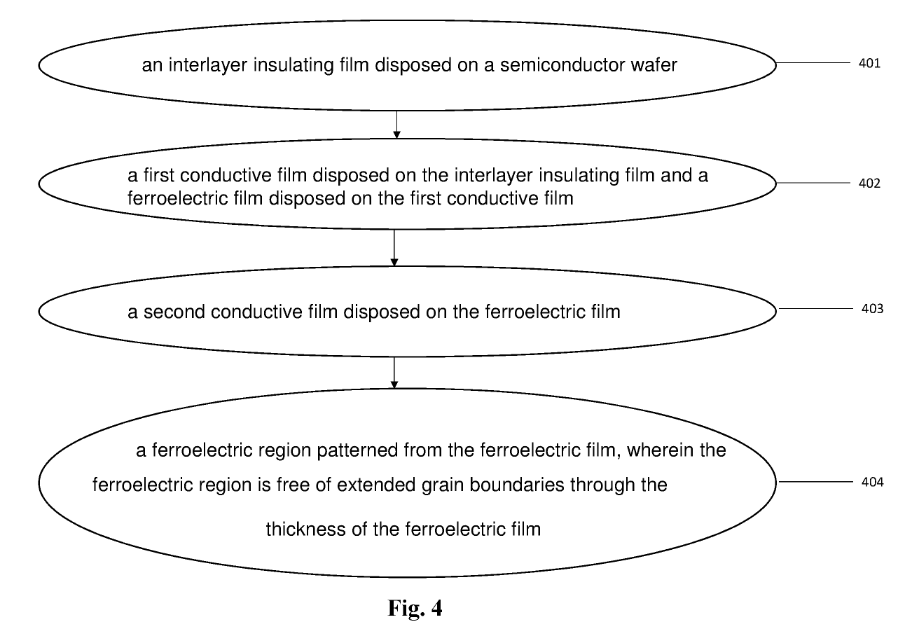

Referring to FIG. 4, which illustrates a flow chart for the circuit structure of FIG. 1. In block 401, an interlayer insulating film 102 is disposed on a semiconductor wafer 101. In block 402, a first conductive film 103 is disposed on the interlayer insulating film 102 and a ferroelectric film 104 is disposed on the first conductive film 103. In block 403, a second conductive film 105 is disposed on the ferroelectric film 104. Finally, in block 404, a ferroelectric region patterned from the ferroelectric film 104, wherein the ferroelectric region is free of extended grain boundaries through a thickness of the ferroelectric film 104.

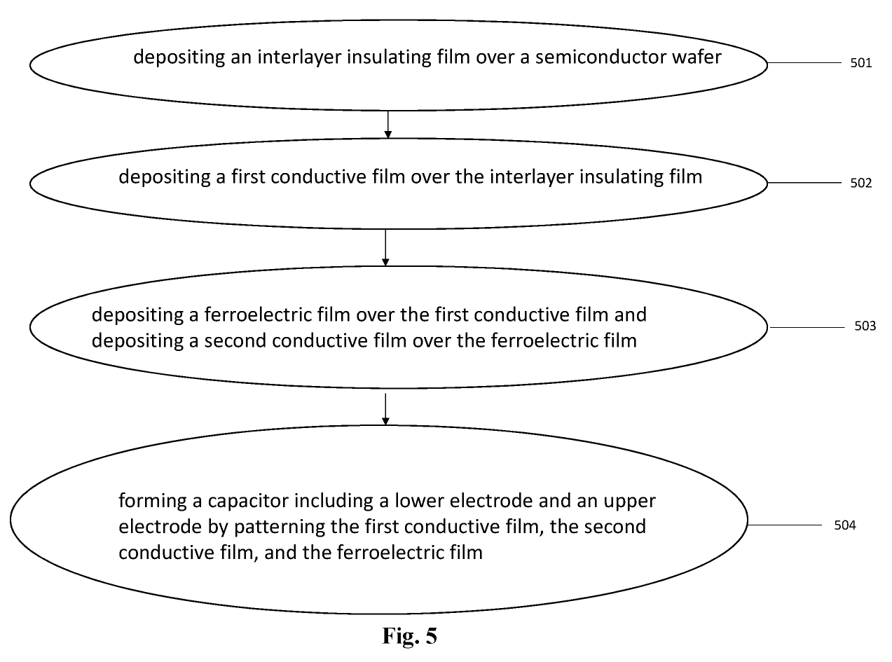

Referring to FIG. 5, which illustrates a flow chart for the circuit structure including a capacitor of FIG. 2. In block 501, interlayer insulating film 202 is deposited over a semiconductor wafer 201. In block 502, a first conductive film 203 is deposited over the interlayer insulating film 202. In block 503, a ferroelectric film 204 is deposited over the first conductive film 203 and a second conductive film 205 is deposited over the ferroelectric film 204. Finally, in block 504, a capacitor is formed including a lower electrode 206 and an upper electrode 207 by patterning the first conductive film 203, the second conductive film 205, and the ferroelectric film 204.

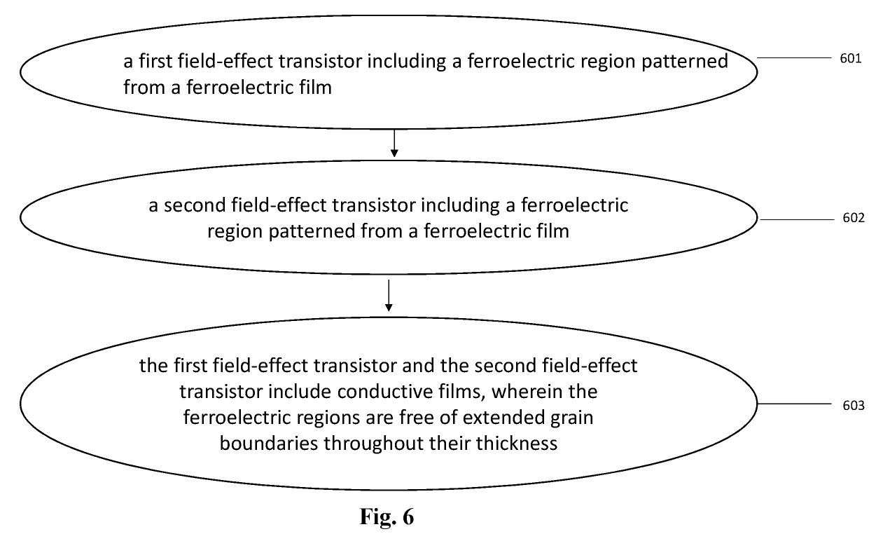

Referring to FIG. 6, which illustrates a flow chart for the circuit structure of FIG. 3. In block 601, a first field-effect transistor 300 including a ferroelectric region is patterned from a ferroelectric film 304. In block 602, a second field-effect transistor 303 including a ferroelectric region patterned from a ferroelectric film 304. Finally, in block 603, the first field-effect transistor 300 and the second field-effect transistor 303 include conductive films 305, wherein the ferroelectric regions are free of extended grain boundaries throughout their thickness.

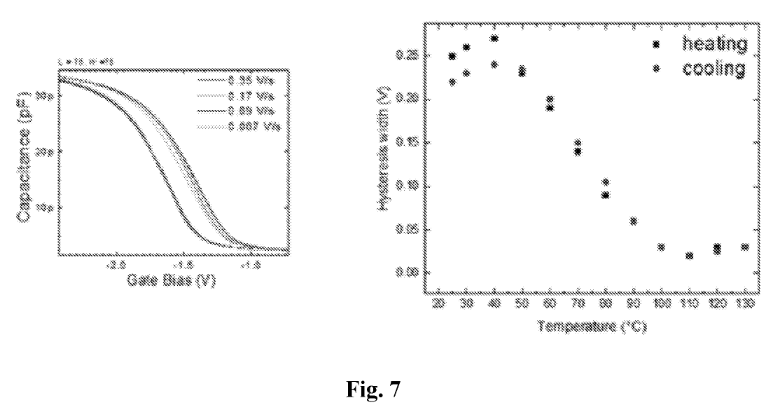

FIG. 7 depicts example graphs that describe the C-V measurements of the capacitor structure

A method of manufacturing a capacitor structure includes forming a silicon wafer and performing field oxide growth over the silicon wafer. The first field oxide growth is about 330 nm. Then resist coat and optical lithography over a first field oxide growth layer is performed. Next, the reactive ion etching over the silicon wafer is performed. This is done to open a capacitor area while leaving about a 30 nm first field oxide growth layer in place over an active area of the first field oxide growth layer. The next step is to resist strip over the first field oxide growth layer. Then, performing BOE 4:1 and 35 seconds to remove the remaining first field layer oxide layer over the active silicon wafer area is done. Next, a second field oxide growth layer is regrown and strontium passivation is deposited for 2 minutes (about 4 monolayers).

The structure is heated at about 760 degrees Celsius for about 30 minutes. Then, a 1.6 nm SrTiO3 is deposited at 400 degrees Celsius in 1×10\hat{ }−8 Torr O2 and 10 nm BaTiO3 is deposited at 500 degrees Celsius in 1×10\hat{ }−7 Torr O2. Next, oxidation at 500 degrees Celsius in 1×10\hat{ }−5 Torr O2 is performed for 40 minutes. Then, cooling to room temperature under a vacuum is performed. Next, an electrode over the second field oxide growth layer is deposited, 20 nm TiN sputtering. Then, a hardmask is deposited over the second field oxide growth layer, 25 nm Si3N4 (PECVD). The next step is to resist coat and optical lithography over the second field layer.

A hardmask patterning over the second field oxide growth layer, BOE 9:1 for 6 minutes is performed. Next a resist strip over the second field oxide growth layer is performed. Then, performing TiN patterning over the second field oxide growth layer is done, H2O2 at 68 degrees Celsius for 5 minutes; and finally the hardmask over the second field oxide growth layer is removed.

Capacitance-voltage (C-V) measurements of this exemplary capacitor structure exhibit a hysteretic response, and the direction of the hysteresis is characteristic of ferroelectric polarization switching. Further, the weak dependence on voltage ramp rate and the reduction of the memory window at temperatures approaching the Curie temperature of BaTiO3 (˜120 C) lend support to an underlying ferroelectric switching mechanism, rather than e.g. ion migration. Finally, the ferroelectric region is glass-ceramic and free of extended grain boundaries through a thickness of the ferroelectric film as determined by transmission electron microscopy.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A circuit comprising:
an interlayer insulating film disposed on a semiconductor wafer;
a first conductive film disposed on the interlayer insulating film;
a ferroelectric film disposed on the first conductive film;
a second conductive film disposed on the ferroelectric film; and
a ferroelectric region patterned from the ferroelectric film,
wherein the ferroelectric region is free of extended grain boundaries through a thickness of the ferroelectric film.

2. The circuit of claim 1, wherein the material of the ferroelectric region comprises a perovskite.

3. The circuit of claim 2, wherein the perovskite material is Barium Titanate (BaTiO₃).

4. The circuit of claim 2, wherein the perovskite material is Lead Zirconium Titanate (PZT).

5. The circuit of claim 2, wherein the perovskite material is Strontium Bismuth Tantalate (SBT).

6. The circuit of claim 1, wherein the ferroelectric region comprises a crystallite having a size smaller than dimensions of the ferroelectric region in the circuit which allows a reduced statistical circuit variability.

7. The circuit of claim 1, wherein the ferroelectric region is amorphous.

8. The circuit of claim 1, wherein the ferroelectric region is nanocrystalline.

9. The circuit of claim 1, wherein the ferroelectric region is glass-ceramic.

10. The circuit of claim 1, wherein the circuit further comprises a capacitor, which includes a lower electrode and an upper electrode.

11. The circuit of claim 10, wherein the lower and upper electrodes are patterned from the first conductive film, the second conductive film, and the ferroelectric film.

12. The circuit of claim 1, further comprising at least one additional film disposed between one or more layers selected from the group consisting of: the interlayer insulating film and the semiconductor wafer; the first conductive film and the interlayer insulating film; the ferroelectric film and the first conductive film; the second conductive film and the ferroelectric film; and any combination thereof.

13. A circuit comprising:
a first field-effect transistor including a ferroelectric region patterned from a ferroelectric film; and
a second field-effect transistor including a ferroelectric region patterned from a ferroelectric film,
wherein the first and second field-effect transistors include a conductive film,
wherein the ferroelectric regions are free of extended grain boundaries throughout their thickness.

14. The circuit of claim 13, wherein the ferroelectric region comprises a crystallite having a size smaller than dimensions of the ferroelectric region in the circuit which allows a reduced statistical circuit variability.

15. The circuit of claim 13, wherein the ferroelectric region is amorphous.

16. The circuit of claim 13, wherein the ferroelectric region is nanocrystalline.

17. The circuit of claim 13, wherein the ferroelectric region is glass-ceramic.

18. A method of manufacturing a circuit, comprising:
depositing an interlayer insulating film over a semiconductor wafer;
depositing a first conductive film over the interlayer insulating film;
depositing a ferroelectric film over the first conductive film;
depositing a second conductive film over the ferroelectric film; and
forming a capacitor which includes a lower electrode and an upper electrode by patterning the first conductive film, the second conductive film, and the ferroelectric film.

19. The method of manufacturing a circuit of claim 18, wherein the method further comprises:
depositing a plug over the upper electrode; and
depositing a plug between the interlayer insulating film.

20. The method of manufacturing a circuit of claim 18, further comprising depositing at least one additional film between one or more layers selected from the group consisting of: the interlayer insulating film and the semiconductor wafer; the first conductive film and the interlayer insulating film; the ferroelectric film and the first conductive film; the second conductive film and the ferroelectric film; and any combination thereof.
